(19) United States
(12) Patent Application Publication
(10) Pub. No.: US 2009/0317978 A1
(43) Pub. Date: Dec. 24, 2009

(54) MANUFACTURING METHOD OF SEMICONDUCTOR DEVICE

(75) Inventor: Kazuyuki HIGASHI, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/487,979

(22) Filed: Jun. 19, 2009

(30) Foreign Application Priority Data
Jun. 19, 2008 (JP) 2008-160784

(51) Int. Cl. H01L 21/311

(52) U.S. Cl. 438/703; 257/E21.249

(57) ABSTRACT

In one aspect of the present invention, a method of manufacturing semiconductor device may include forming a second core on a member to be processed, and a first core on the second core, the second core located below the first core and having a width larger than that of the first core, forming a coating film on a top surface and side surfaces of the first core, and a top surface and side surfaces of the second core, processing the coating film into sidewall masks by partially removing the coating film in a manner that portions of the coating film, which are located on the side surfaces of the first and second cores, are left remaining, etching the first and second cores by using the sidewall masks as a mask so as to remove the first core and portions of the second core which are not covered with the sidewall masks from above, so that an etching mask including the sidewall masks and portions of the second core which remain directly below the sidewall masks is formed, and etching the member by using the etching mask as a mask, so that the member is patterned.

### CROSS REFERENCE TO RELATED APPLICATION

This application is based upon and claims the benefit of priority from Japanese Patent Application No. 2008-160784, filed on Jun. 19, 2008, the entire contents of which are incorporated herein by reference.

### BACKGROUND

With miniaturization of semiconductor elements, there is a demand for methods for forming a pattern with dimensions smaller than a resolution limit (also referred to as a limit line-width for exposure or a limit pitch for exposure) of lithography. A conventional method is a method in which sidewall patterns are formed respectively on side surfaces of dummy patterns (cores), and then, a film to be processed is etched by using the sidewall pattern as a mask.

According to the conventional method, after sidewall patterns are formed, the dummy pattern between the adjacent sidewall patterns is removed by wet processing, so that a fine mask composed of the sidewall patterns is formed. In these days, further reduction in pattern dimensions and further miniaturization of pattern pitch have been demanded for such a pattern forming method using sidewall patterns.

### SUMMARY

Aspects of the invention relate to an improved method of a manufacturing semiconductor device.

In one aspect of the present invention, a method of manufacturing semiconductor device may include forming a second core on a member to be processed, and a first core on the second core, the second core located below the first core and having a width larger than that of the first core, forming a coating film on a top surface and side surfaces of the first core, and a top surface and side surfaces of the second core, processing the coating film into sidewall masks by partially removing the coating film in a manner that portions of the coating film, which are located on the side surfaces of the first and second cores, are left remaining, etching the first and second cores by using the sidewall masks as a mask so as to remove the first core and portions of the second core which are not covered with the sidewall masks from above, so that an etching mask including the sidewall masks and portions of the second core which remain directly below the sidewall masks is formed, and etching the member by using the etching mask as a mask, so that the member is patterned.

In another aspect of the invention, a method of manufacturing semiconductor device may include forming a plurality of m cores (m is a positive integer) at an arrangement pitch P sequentially on a member to be processed, the m cores having successively increasing widths from the uppermost core, forming a coating film, so that side surfaces of the respective m cores are covered with the coating film, processing the coating film into sidewall masks by partially removing the coating film in a manner that portions of the coating film, which are located respectively on the side surfaces of the m cores, are left remaining, etching the m cores by using the sidewall masks as a mask so as to remove the first core at the top among the m cores and to remove portions, which are not covered with the sidewall masks from above, of the second to m-th cores from the top, thereby forming an etching mask including the sidewall masks and portions, which remain directly below the sidewall masks, of the second to the m-th cores, and etching the member by using the etching mask as a mask, so that the member is patterned, wherein the m cores are formed so that the width of the n-th core (n is an integer between 1 and m inclusive) from the top becomes approximately (4n−3)P/(4m), and each of the sidewall masks is formed to have a width of approximately P/(4m).

### BRIEF DESCRIPTIONS OF THE DRAWINGS

A more complete appreciation of the invention and many of the attendant advantages thereof will be readily obtained as the same becomes better understood by reference to the following detailed description if considered in connection with the accompanying drawings.

FIGS. 1A to 1D are cross-sectional views illustrating processes of manufacturing a semiconductor device according to the general explanation of embodiments.

FIGS. 2A to 2I are cross-sectional views illustrating processes of manufacturing a semiconductor device according to a first embodiment.

FIGS. 3A to 3K are cross-sectional views illustrating processes of manufacturing a semiconductor device according to a second embodiment.

FIGS. 4A to 4F are cross-sectional views illustrating processes of manufacturing a semiconductor device according to a third embodiment.

FIGS. 5A to 5K are cross-sectional views illustrating processes of manufacturing a semiconductor device according to a fourth embodiment.

FIGS. 6A to 6E are cross-sectional views illustrating processes of manufacturing a semiconductor device according to a fifth embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### General Explanation of Embodiments

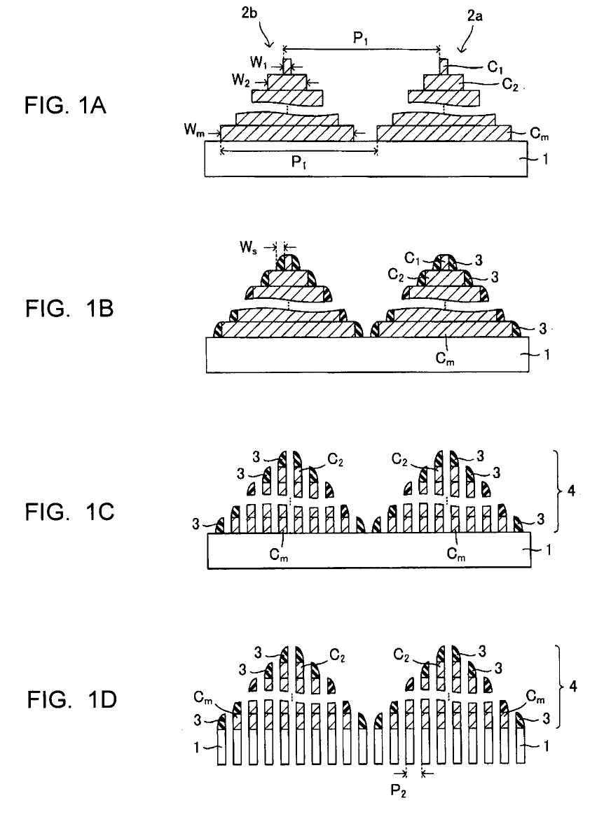

FIGS. 1A to 1D are cross-sectional views illustrating processes of manufacturing a semiconductor device according to a general explanation of embodiments of the present invention.

First, as illustrated in FIG. 1A, cores 2a and 2b are formed on a member 1 to be processed (hereinafter, referred to as a processed member 1).

Each of the cores 2a and 2b is formed of m stages (m is a positive integer) in cross section. These m stages are formed respectively of first to m-th stages of cores C1 to Cm from the top. Among the cores C1 to Cm, the lower the core stage is located, the larger the width of the core stage is. Note that, the cores C1 to Cm may be separately formed by stacking individual members respectively for the cores C1 to Cm, or may be integrally formed of a single material.

Next, as illustrated in FIG. 1B, sidewall masks 3 are formed respectively on side surfaces of the first to m-th cores C1 to Cm in the following manner.

First, a coating film is formed to cover exposed upper and side surfaces of the first to m-th cores C1 to Cm. Then, the coating film thus formed is partially removed in such a manner that portions of the coating film, which are located respectively on the side surfaces of the first to m-th cores C1 to Cm, are left remaining.

After that, as illustrated in FIG. 1C, etching is performed using the sidewall masks 3 as a mask, so that portions, not covered with the sidewall masks 3 from above, of the first to m-th cores C1 to Cm are removed. As a result, an etching mask 4 is obtained which is formed of the sidewall masks 3 and portions, remaining just below the sidewall masks 3, of the second to m-th cores C2 to Cm.

Subsequently, as illustrated in FIG. 1D, etching is performed using the etching mask 4 as a mask, so that the processed member 1 is patterned.

If a line-and-space pattern having constant width and interval is formed in the processed member 1 by the above-described method, the relation expressed by the following mathematical formulas may be satisfied:

$${W}_{n} = \frac{( 4 n - 3 )}{4 m} {P}_{1} , ( 1 \leq n \leq m ) \\ {W}_{s} = \frac{1}{4 m} {P}_{1} \qquad [ Mathematical Formulas 1 ]$$

where P1 denotes the pitch at which the cores 2a and 2b are arranged (the pitch of each of the first to m-th cores C1 to Cm); Wn denotes the width of the n-th core Cn (n is an integer between 1 and m inclusive); and Ws denotes the width of each sidewall mask 3.

In the formation, each of the width and the interval of the pattern formed in the processed member 1 by use of the etching mask 4 is equal to Ws, and the pitch P2 of the pattern is expressed by the following mathematical formula:

$${P}_{2} = 2 {W}_{s} = \frac{1}{2 m} {P}_{1} \qquad [ Mathematical Formula 2 ]$$

### First Embodiment

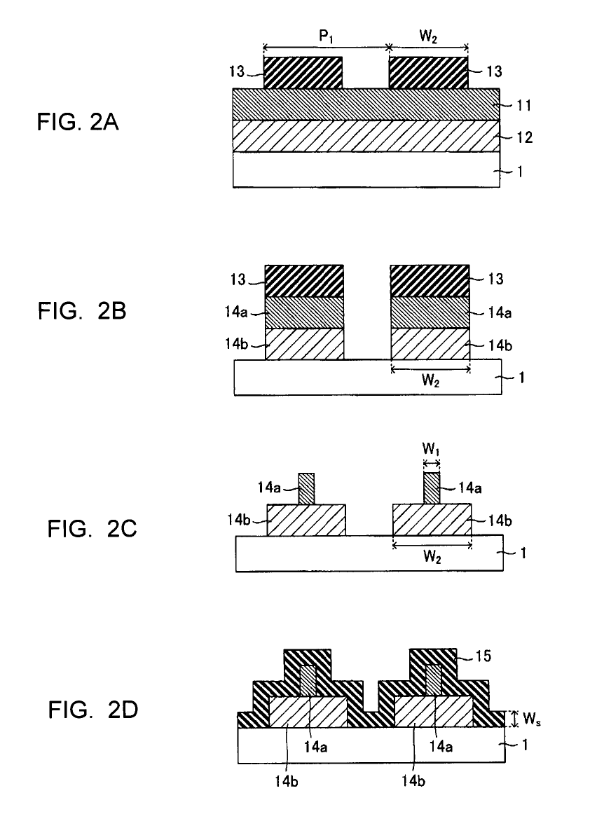

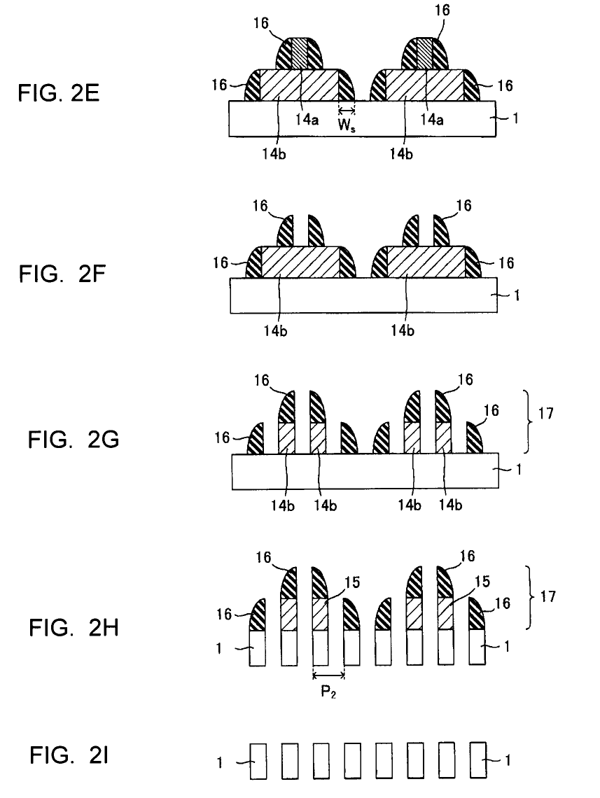

FIGS. 2A to 2I are cross-sectional views illustrating processes of manufacturing a semiconductor device according to a first embodiment.

First, as illustrated in FIG. 2A, a second sacrificial film 12, a first sacrificial film 11, and a resist 13 having a line-and-space pattern having a pitch P1 are sequentially stacked on a processed member 1 formed on an unillustrated semiconductor substrate, for example. Note that, the pitch P1 is not necessarily constant.

The resist 13 is patterned by lithography, reactive ion etching (RIE), and the like. Since the pattern width of the resist 13 becomes substantially equal to the width W2 of a second core 15 which will be described later, the pattern width of the resist 13 can be determined according to the width W2 of the second core 15.

Here, the processed member 1 is, for example, a gate material film or a hard mask on a subject to be processed. In addition, the processed member 1 may be a film formed of a plurality of layers, and may be, for example, any one of a control electrode film, an inter-electrode insulating film, and a floating gate electrode film, which form a stack-gate structure of a flash memory. Moreover, the subject to be processed (a member to be processed) may be the semiconductor substrate itself.

The materials of the first and second sacrificial films 11 and 12 to be combined are selected from those having high etching selective ratios. In addition, each of the materials of the first and second sacrificial films 11 and 12 is required to have a high etching selective ratio to the material of the processed member 1. For example, if the processed member 1 is made of SiN, the material to be used for the first sacrificial film 11 may be SiO₂ or the like, while the material to be used for the second sacrificial film 12 may be C, SiC, W, Ta, or the like. If the processed member 1 is made of SiO₂, the material to be used for the first sacrificial film 11 may be SiN or the like, while the material to be used for the second sacrificial film 12 may be C, SiC, W, Ta, or the like.

In processes described below, for example, a hydrofluoric acid (HF) solution or a fluorocarbon (CF)-based gas is used in processing or removal of a member made of SiO₂. In addition, for example, a phosphoric acid solution or a CF-based gas is used in processing or removal of a member made of SiN. Further, for example, an oxygen gas is used in processing or removal of a member made of C.

Next, as illustrated in FIG. 2B, etching is performed using the resist 31 as a mask, so that the pattern of the resist 13 is transferred to the first and second sacrificial films 11 and 12. As a result, the first and second sacrificial films 11 and 12 are thereby processed respectively into cores 14a and 14b. The etching of the first and second sacrificial films 11 and 12 is performed by anisotropic etching, RIE or the like.

Then, as illustrated in FIG. 2C, the cores 14a are subjected to a slimming process by wet processing or the like so as to have a reduced width. Here, W1 denotes the width of each core 14a after the slimming process. Note that, the resist 13 is removed before or after the slimming process.

Subsequently, as illustrated in FIG. 2D, a coating film 15 is formed by chemical vapor deposition (CVD) or the like in such a manner that the exposed upper and side surfaces of the cores 14a and 14b are conformally coated with the coating film 15.

Here, since the thickness of the coating film 15 is substantially equal to the width Ws of a sidewall mask 16 which will be described later, the thickness of the coating film 15 can be determined according to the width Ws of the sidewall mask 16. Meanwhile, the coating film 15 is formed of a material that is capable of obtaining a high etching selective ratio to the processed member 1, as well as to the cores 14a and 14b. For example, if the processed member 1, each core 14a, and each core 14b are formed respectively of SiN, SiO₂, and C, the material to be used for the coating film 15 may be amorphous Si.

Next, as illustrated in FIG. 2E, the coating film 15 is partially removed in such a manner that portions of the coating film 15 located respectively on the side surfaces of the cores 14a and 14b are left remaining. The coating film 15 is thereby processed into the sidewall masks 16. Here, the width of each sidewall mask 16 is denoted by Ws.

Then, as illustrated in FIG. 2F, the core 14a is selectively removed by wet processing or the like.

Subsequently, as illustrated in FIG. 2G, etching is performed using the sidewall masks 16 as a mask, so that portions, not covered with the sidewall masks 16 from above, of the cores 14b are removed. As a result, an etching mask 17 formed of the sidewall masks 16 and portions, remaining just below the sidewall masks 16, of the cores 14b is obtained. The etching of the cores 14b is performed by RIE or the like.

After that, as illustrated in FIG. 2H, etching is performed using the etching mask 17 as a mask, so that the processed member 1 is patterned. Here, the pattern pitch of the line-and-space pattern formed in the processed member 1 is denoted by P2. Note that, the width and interval of the line-and-space pattern formed in the processed member 1 are not necessarily constant. In the case where the width and interval of the line-and-space pattern are not constant, the pattern pitch P2 is also not constant.

The etching of the processed member 1 is performed by RIE or the like. Note that, as to a region where the etching mask 17 is continuous on an end portion of the line-and-space pattern, the corresponding portion of the pattern is appropriately separated by lithography, RIE, and the like.

Next, as illustrated in FIG. 2I, the etching mask 17 on the processed member 1 is removed. The removal of the etching mask 17 is performed by wet processing, RIE, or the like.

According to the first embodiment, it is possible to form a finer line-and-space pattern than that by the conventional pattern-forming method using a sidewall mask.

In addition, if a line-and-space pattern having constant width and constant interval is to be formed in the processed member 1 by the above-described method, the pattern pitch P1 of the resist 13 is constant, and the relation expressed by the following mathematical formulas may be satisfied:

$${W}_{1} = {W}_{s} = \frac{1}{8} {P}_{1} \\ {W}_{2} = \frac{5}{8} {P}_{1} \qquad [ Mathematical Formulas 3 ]$$

where P1 denotes the pattern pitch, W1 denotes the width of each core 14a, W2 denotes the width of each core 14b, and Ws denotes the width of each sidewall mask 16.

Here, W1 in Mathematical Formulas b 3 is equal to a value obtained by substituting 2 and 1 respectively into m and n in the formula of Wn in Mathematical Formulas 1 described before. W2 in Mathematical Formulas 3 is equal to a value obtained by substituting 2 and 2 respectively into m and n in the formula of Wn in Mathematical Formulas 1 described before. Ws in Mathematical Formulas 3 is equal to a value obtained by substituting 2 into m in the formula of Ws in Mathematical Formulas 1 described before.

At this time, the width and the interval of the pattern formed in the processed member 1 are equal respectively to the width W1 of each core 14a and the width Ws of each sidewall mask 16, and thus, the pitch P2 of the pattern is constant and is expressed by the following mathematical formula:

$${P}_{2} = 2 {W}_{s} = \frac{1}{4} {P}_{1} \qquad [ Mathematical Formula 4 ]$$

Specifically, is the pattern pitch P1 of the resist 13 is a limit pitch for exposure of lithography, the first embodiment allows a pattern with a pitch that is one-fourth of the limit pitch for exposure to be formed on the processed member 1.

Here, P2 in Mathematical Formula 4 is equal to a value obtained by substituting 2 into m in the formula of Pn in Mathematical Formula 2 described before.

### Second Embodiment

A second embodiment is different from the first embodiment in that each of cores is formed to have a desired width by performing a slimming process on a resist instead of using a sacrificial film. Note that, the same points in the second embodiment as those in the first embodiment are not described or are described in brief.

Hereinafter, a case of forming three stages of cores (three stages of sidewall masks) will be described as an example. In practice, however, it is possible to form any number of two or more stages of cores as long as a desired processing accuracy is maintained.

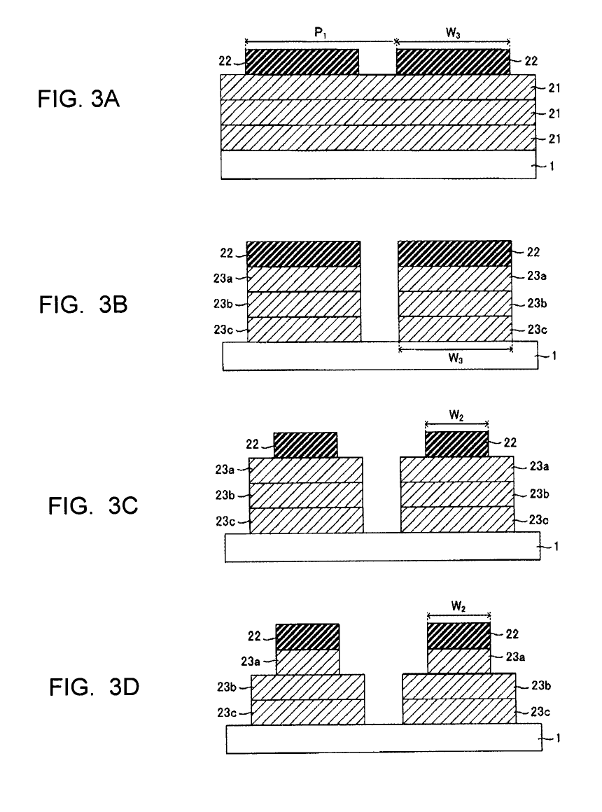

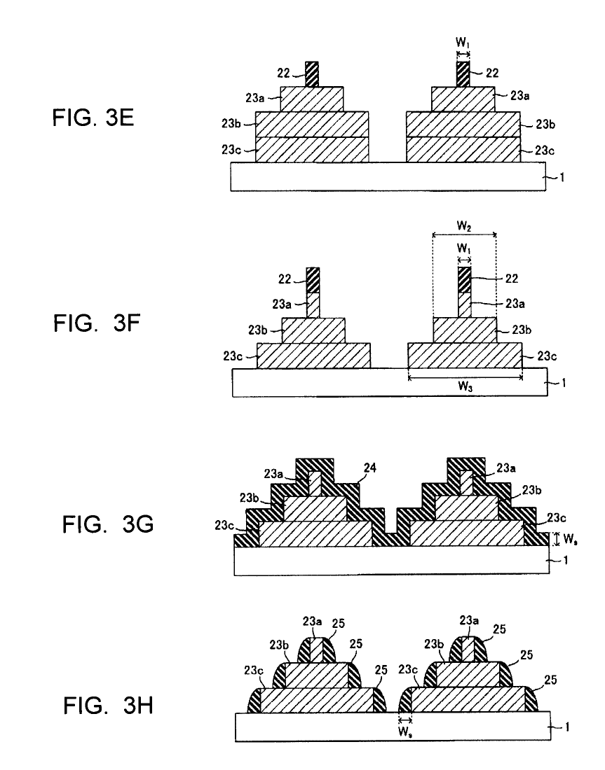

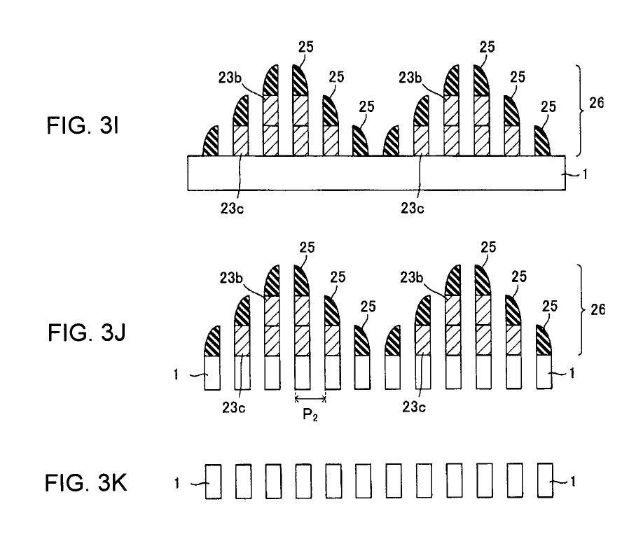

FIGS. 3A to 3K are cross-sectional views illustrating processes of manufacturing a semiconductor device according to the second embodiment of the present invention.

First, as illustrated in FIG. 3A, sacrificial films 21c, 21b, and 21a as well as a resist 22 having a line-and-space pattern having a pitch P1 are sequentially stacked on a processed member 1 formed on an semiconductor substrate (not shown), for example. Note that, the pitch P1 is not necessarily constant. In addition, an etching stopper film having a high etching selective ratio to the sacrificial films 2a, 21b, and 21c may be formed between the sacrificial films 21a and 21b, and between the sacrificial films 21b and 21c.

The resist 22 is patterned by lithography, RIE, and the like. Since the pattern width of the resist 22 becomes substantially equal to the width W3 of a core 23c which will be described later, the pattern width of the resist 22 can be determined according to the width W3 of the core 23c.

The sacrificial films 2a, 21b, and 21c may be formed of the same material, or may be formed of different materials from one another. Alternatively, the sacrificial films 2a, 21b, and 21c may be integrally formed of a single material. In addition, the materials of the sacrificial films 2a, 21b, and 21c are required to have a high etching selective ratio to the material of the processed member 1. For example, if the processed member 1 is made of SiO₂, the material to be used for the sacrificial films 2a, 21b, and 21c may be: an insulating material, such as SiN, C, or SiC; a metal, such as W, Ti, Al, or Ta; or a nitride or an oxide of any of these metals.

Next, as illustrated in FIG. 3B, etching is performed using the resist 22 as a mask, so that the pattern of the resist 22 is transferred to the sacrificial films 2a, 21b, and 21c. As a result, the sacrificial films 2a, 21b, and 21c are processed respectively into cores 23a, 23b, and 23c. The etching of the sacrificial films 2a, 21b, and 21c is performed by RIE or the like.

Next, as illustrated in FIG. 3C, the resist 22 is subjected to a slimming process by chemical dry etching (CDE) so as to have a reduced width. Here, since the width of the resist 22 after the slimming process becomes substantially equal to the final width W2 of the core 23b, the pattern width of the resist 22 after the slimming process can be determined according to the width W2 of the core 23b.

Next, as illustrated in FIG. 3D, etching is performed using the resist 22 having the reduced width as a mask, the width of the core 23a is reduced. The etching of the core 23a is performed by RIE or the like. At this time, if no etching stopper film is formed between the cores 23a and 23b, it is preferable to inhibit the etching from eroding the core 23b by controlling the etching time, or the like.

Next, as illustrated in FIG. 3E, the resist 22 is subjected again to a slimming process by CDE or the like so as to have a further reduced width. At this time, since the width of the resist 22 after the slimming process becomes substantially equal to the final width W1 of the core 23a, the pattern width of the resist 22 after the slimming process can be determined according to the width W1 of the core 23a.

Next, as illustrated in FIG. 3F, etching is performed using the resist 22 having the further reduced width as a mask, so that the widths of the cores 23a and 23b are reduced. At this time, exposed parts of the respective upper surfaces of the cores 23a and 23b are etched, so that the pattern of the resist 22 is transferred to the core 23a, and that the pattern of the core 23a at the time illustrated in FIG. 3E is transferred to the core 23b. The etching of the cores 23a and 23b is performed by RIE or the like. At this time, if no etching stopper film is formed between the cores 23a and 23b, and between the cores 23b and 23c, it is preferable to inhibit the etching from eroding the core 23c and a portion, covered with the core 23a from above, of the core 23b, by controlling the etching time, or the like.

Next, as illustrated in FIG. 3G, after the resist 22 is removed, a coating film 24 is formed by CVD or the like so as to conformally cover the exposed upper and side surfaces of the cores 23a, 23b, and 23c. Here, the thickness of the coating film 24 becomes substantially equal to the width Ws of a sidewall mask 25 which will be described later.

Next, as illustrated in FIG. 3H, the coating film 24 is partially removed by RIE or the like in such a manner that portions of the coating film 24, which are located respectively on the side surfaces of the cores 23a, 23b, and 23c, are left remaining. In this way, the coating film 24 is processed into the sidewall masks 25. Here, Ws denotes the width of each sidewall mask 25.

Next, as illustrated in FIG. 3I, etching is performed using the sidewall masks 25 as a mask, so that the cores 23a are removed and that the cores 23b and 23c are partially removed at their portions which are not covered with the sidewall masks 25 from above. As a result, an etching mask 26 is obtained, which is formed of the sidewall masks 25 and portions, which remain just below the sidewall masks 25, of the cores 23b and 23c. The etching of the cores 23a, 23b, and 23c is performed by RIE or the like.

Next, as illustrated in FIG. 3J, etching is performed using the etching mask 26 as a mask, so that the processed member 1 is patterned. Here, the pattern pitch of the line-and-space pattern formed in the processed member 1 is denoted by P2. Note that, the width and interval of the line-and-space pattern formed in the processed member 1 are not necessarily constant. In the case where the width and interval of the line-and-space pattern are not constant, the pattern pitch P2 is also not constant. The etching of the processed member 1 is performed by RIE or the like.

Next, as illustrated in FIG. 3K, the etching masks 26 on the processed member 1 are removed. The removal of the etching masks 26 is performed by wet processing, RIE, or the like.

According to the second embodiment, it is possible, as in the first embodiment, to form a finer line-and-space pattern than that by the conventional pattern-forming method using a sidewall mask.

In addition, if a line-and-space pattern having constant width and constant interval is to be formed in the processed member by the above-described method, the pattern pitch P1 of the resist 22 is constant, and the relation expressed by the following mathematical formulas may be satisfied:

$${W}_{1} = {W}_{s} = \frac{1}{12} {P}_{1} \\ {W}_{2} = \frac{5}{12} {P}_{1} \\ {W}_{3} = \frac{9}{12} {P}_{1} \qquad [ Mathematical Formulas 5 ]$$

where P1 denotes the pattern pitch, W1 denotes the width of the core 23a, W2 denotes the width of the core 23b, W3 denotes the width of the core 23c, and Ws denotes the width of each sidewall mask 25.

Here, W1 in Mathematical Formulas 5 is equal to a value obtained by substituting 3 and 1 respectively into m and n in the formula of Wn in Mathematical Formulas 1 described above. W2 in Mathematical Formulas 5 is equal to a value obtained by substituting 3 and 2 respectively into m and n in the formula of Wn in Mathematical Formulas 1 described above. W3 in Mathematical Formulas 5 is equal to a value obtained by substituting 3 and 3 respectively into m and n in the formula of Wn in Mathematical Formulas 1 described above. Ws in Mathematical Formulas 5 is equal to a value obtained by substituting 3 into m in the formula of Ws in Mathematical Formulas 1 described before.

In this case, the width and the interval of the pattern formed in the processed member 1 are equal to Ws, and thus, the pitch P2 of the pattern is constant and is expressed by the following mathematical formula:

$${P}_{2} = 2 {W}_{s} = \frac{1}{6} {P}_{1} \qquad [ Mathematical Formula 6 ]$$

Specifically, if the pattern pitch P1 of the resist 22 is a limit pitch for exposure of lithography, the second embodiment allows a pattern with a pitch that is one-sixth of the limit pitch for exposure to be formed on the processed member 1.

Here, P2 in Mathematical Formula 6 is equal to a value obtained by substituting 3 into m in the formula of Pn in Mathematical Formula 2 described before.

Note that, in the second embodiment, four or more stages of cores may be formed by using four or more sacrificial films. In this case, if m denotes the number of stages of cores (m is a positive integer), the relation expressed by Mathematical Formulas 1 described above may be satisfied in order to form a line-and-space pattern with constant width and interval in the processed member 1, where P1 denotes the pattern pitch of the resist 22 (the pitch of each of the first to m-th cores from the top), Wn denotes the width of the n-th core from the top (n is an integer between 1 and m inclusive), and Ws denotes the width of each sidewall mask 25. As a result, the pattern with the pitch P2 expressed by Mathematical Formula 2 described above is formed in the processed member 1.

In this case, the pattern width of the resist 22 patterned by lithography, RIE, and the like in the process illustrated in FIG. 3A becomes substantially equal to the width Wm of the m-th core from the top (the lowermost core). In addition, the pattern width of the resist 22 having the reduced width by the slimming process in the process illustrated in FIG. 3C becomes substantially equal to the width Wm−1 of the m−1-th core (the second core from the bottom) from the top. Moreover, the pattern width of the resist 22 having the further reduced width by the slimming process in the process illustrated in FIG. 3E becomes substantially equal to the width Wm−2 of the m-2-th core (the third core from the bottom) from the top. Subsequently, the slimming of the resist 22 and the etching, using as a mask the resist 22 subjected to the slimming process, of the cores therebelow are repeated in the same manner as described above until the pattern width of the resist 22 becomes equal to the width W1 of the uppermost core. The slimming process on the resist 22 is performed m-1 times in total.

### Third Embodiment

The third embodiment is different from the second embodiment in that each core is formed to have a desired width in a way that a three-dimensional concave and convex pattern is transferred to a resist by an embossing technique such as a nanoimprinting technology instead of the slimming process. Note that, the same points in the third embodiment as those in the second embodiment are not described or are described in brief.

Hereinafter, a case of forming three stages of cores (three stages of sidewall masks) will be described as an example. In practice, however, it is possible to form any number of two or more stages of cores as long as a desired processing accuracy is maintained.

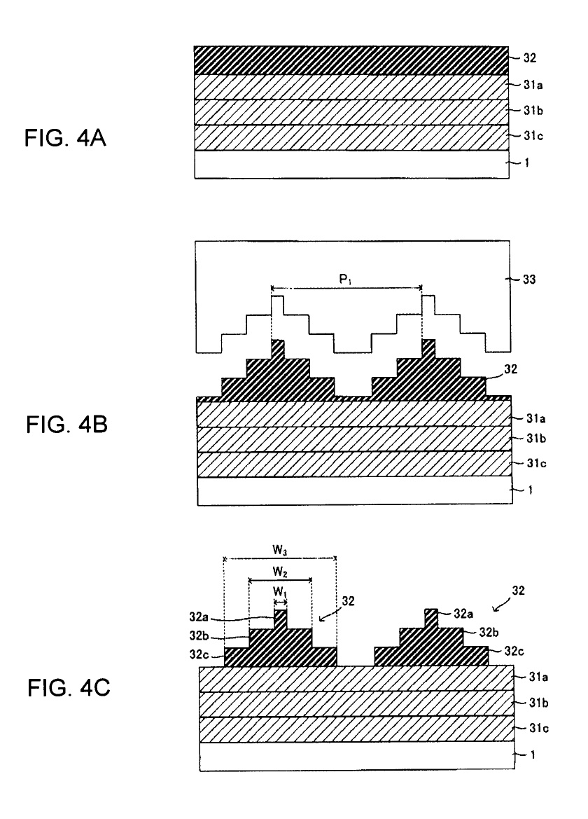

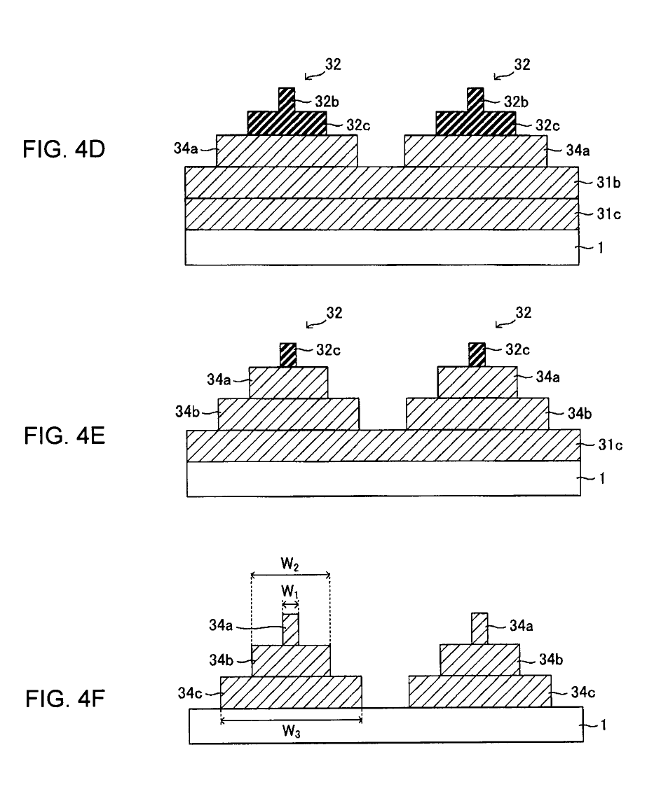

FIGS. 4A to 4F are cross-sectional views illustrating processes of manufacturing a semiconductor device according to the third embodiment.

First, as illustrated in FIG. 4A, sacrificial films 31c, 31b, and 31a as well as a resist 32 are sequentially stacked on a processed member 1 formed on an unillustrated semiconductor substrate, for example.

The sacrificial films 3a, 31b, and 31c can be formed of the same material as that used for forming the sacrificial films 2a, 21b, and 21c according to the second embodiment.

Next, as illustrated in FIG. 4B, a concave and convex pattern is transferred to the resist 32 by an embossing technique using a template 33. The template 33 has a three-dimensional concave and convex pattern corresponding to the final shapes of cores 34a, 34b, and 34c which will be described later, and the concave and convex pattern is transferred to the cores 34a, 34b, and 34c by pressing the template 33 to the resist 32. Here, the concave and convex pattern includes layers having the same widths as the final widths W1, W2, and W3 of the cores 34a, 34b, and 34c, respectively. Hereinbelow, the pitch of each layer of the concave and convex pattern is denoted by P1. Note that, the pitch P1 is not necessarily constant.

Note that, as the embossing technique, it is possible to employ a nanoimprinting technology, such as a thermal nanoimprinting technology or a photo nanoimprinting technology. Specifically, in the case of employing the thermal nanoimprinting technology, a thermoplastic resin is used for the resist 32. After the resist 32 is heated to the glass transition temperature or more so as to be softened, the template 33 is pressed against the resist 32 thus softened. On the other hand, in the case of employing the photo nanoimprinting technology, a photo-curing resin is used for the resist 32. After the template 33 is pressed against the resist 32, the resist 32 is irradiated with ultraviolet rays so at to be hardened.

Next, the upper surface of the resist 32 is removed by etching such as RIE. FIG. 4C illustrates a state where part of the upper surface of the sacrificial film 31a is exposed after the lowermost layer of the resist 32 is removed. At this time, the resist 32 has a shape formed of three layers. Here, the layers of the resist 32 are denoted by 32a, 32b, and 32c, respectively from the top. The layers 32a, 32b, and 32c have the widths W1, W2, and W3, respectively.

FIG. 4D shows a state after etching is further continued, so that the layer 32a of the resist 32 is almost completely removed. At this time, exposed parts of the respective upper surfaces of the layers 32a, 32b, and 32c of the resist 32 as well as the sacrificial film 31a are etched. As a result, the pattern of the layer 32a at the time illustrated in FIG. 4C, the pattern of the layer 32b at the time illustrated in FIG. 4C, and the pattern of the layer 32c at the time illustrated in FIG. 4C are transferred respectively to the layer 32b, the layer 32c, and the sacrificial film 31a. In this way, the sacrificial film 31a is processed into the core 34a.

Note that, in this process, it is preferable that the layer 32a of the resist 32 be removed almost at the same time as the part of the sacrificial film 31b is exposed by the removing of the part of the sacrificial film 31a. To achieve this, it is required to set the thicknesses of the sacrificial film 31a and the layer 32a in accordance with the etching selective ratio between the material of the sacrificial film 31a and the material of the resist 32. In addition, the relation in thickness between the sacrificial film 31b and the layer 32b as well as the relation in thickness between the sacrificial film 31c and the layer 32c are also the same as the relation in thickness between the sacrificial film 31a and the layer 32a. Moreover, the sacrificial films 3a, 31b, and 31c are preferably made to have the same thickness. In this case, the layers 32a, 32b, and 32c are also preferably made to have the same thickness.

FIG. 4E illustrates a state after etching is further continued, so that the layer 32b of the resist 32 is almost completely removed. At this time, exposed parts of the respective upper surfaces of the layers 32b and 32c of the resist 32 as well as the core 34a and the sacrificial film 31b are etched. As a result, the pattern of the layer 32b at the time illustrated in FIG. 4D, the pattern of the layer 32c at the time illustrated in FIG. 4D, the pattern of the core 34a at the time illustrated in FIG. 4D are transferred respectively to the layer 32c, the core 34a, and the sacrificial film 31b. In this way, the sacrificial film 31b is processed into the core 34b.

FIG. 4F illustrates a state after etching is further continued, so that the resist 32 is almost completely removed. At this time, exposed parts of the respective upper surfaces of the layer 32c of the resist 32, the cores 34a and 34b, as well as the sacrificial film 31c are etched. As a result, the pattern of the layer 32c at the time illustrated in FIG. 4E, the pattern of the core 34a at the time illustrated in FIG. 4E, and the pattern of the core 34b at the time illustrated in FIG. 4E are transferred respectively to the core 34a, the core 34b, and the sacrificial film 31c. In this way, the sacrificial film 31c is processed into the core 34c. The widths of the cores 34a, 34b, and 34c at this time are represented respectively by W1, W2, and W3.

Thereafter, the processes after the process of forming the coating film 24 illustrated in FIG. 3G are performed in the same manner as that in the second embodiment.

According to the third embodiment, it is possible to form the cores 34a, 34b, and 34c in desired shapes by using an embossing technique such as a nanoimprinting technology, instead of performing the slimming process on a resist, a sacrificial film, and the like. In addition, it is possible to obtain the same effect as that of the second embodiment.

Note that, the concave and convex pattern can be transferred directly to the sacrificial films 31a, 31b, and 31c by the embossing technique without using the resist 32. In this case, however, it is necessary to select the materials of the sacrificial films 3a, 31b, and 31c from materials to which the concave and convex pattern can be transferred by the nanoimprinting technology. This necessity may possibly lead to difficulties in obtaining a high etching selective ratio to the material of the sidewall masks and difficulties in maintaining a desired processing accuracy in etching.

In addition, in the third embodiment, four or more stages of cores may be formed by increasing the number of layers of the concave and convex pattern of the template 33. In this case, if m denotes the number of stages of cores (m is a positive integer), the relation expressed by the Mathematical Formulas 1 described above may be satisfied in order to form a line-and-space pattern with constant width and interval in the processed member 1, where P1 denotes the pitch of each layer of the concave and convex pattern transferred to the resist 32 by the template 33 (the pitch of each of the first to m-th cores from the top), Wn denotes the width of the n-th core from the top (n is an integer between 1 and m inclusive), and Ws denotes the width of each sidewall mask. As a result, the pattern with the pitch P2 expressed by Mathematical Formula 2 described above is formed in the processed member 1.

### Fourth Embodiment

The fourth embodiment is different from the second embodiment in that each core is formed to have a desired width in a way that a tapered dimension-adjustment film is formed between two sacrificial films instead of the slimming process. Note that, the same points in the fourth embodiment as those in the second embodiment are not described or are described in brief.

Hereinafter, a case of forming three stages of cores (three stages of sidewall masks) will be described as an example. In practice, however, it is possible to form any number of two or more stages of cores as long as a desired processing accuracy is maintained.

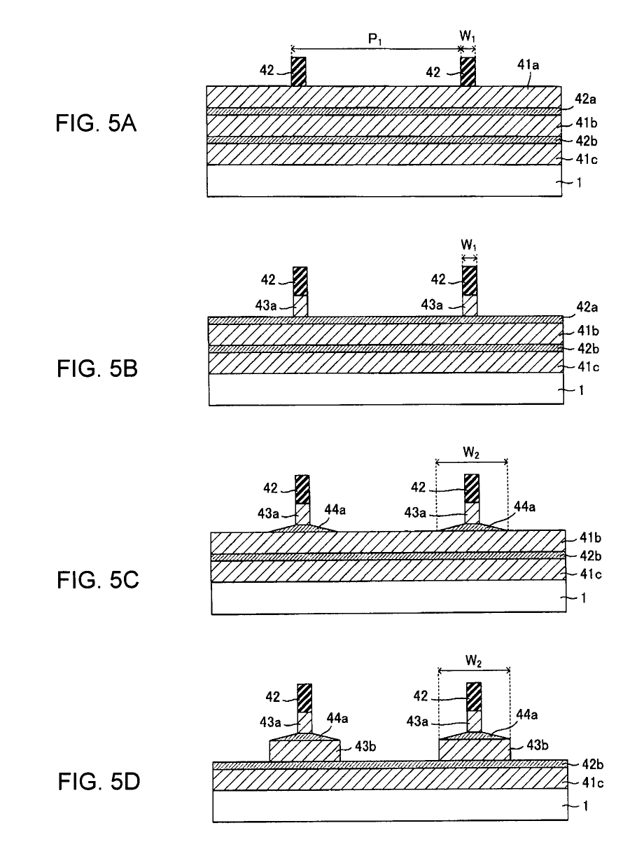

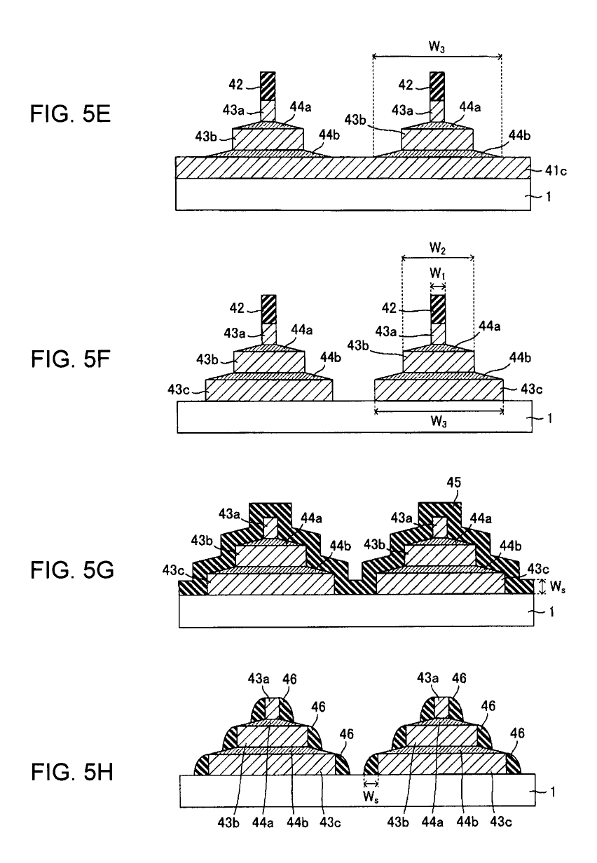

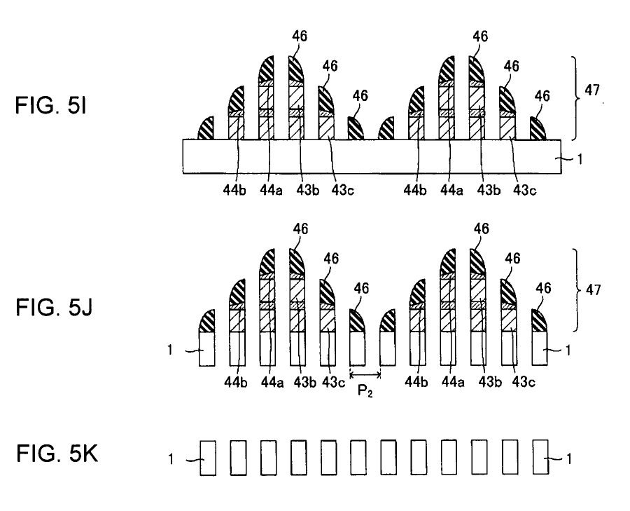

FIGS. 5A to 5K are cross-sectional views illustrating processes of manufacturing a semiconductor device according to the fourth embodiment.

First, as illustrated in FIG. 5A, a first sacrificial film 41c, a second sacrificial film 42b, a first sacrificial film 41b, a second sacrificial film 42a, a first sacrificial film 41a, and a resist 42 having a line-and-space pattern with a pitch P1 are sequentially stacked on a processed member 1 formed on an semiconductor substrate (not shown), for example. Note that, the pitch P1 is not necessarily constant.

The resist 42 is patterned by lithography, RIE, and the like. Since the pattern width of the resist 42 becomes substantially equal to the width W1 of a core 43a which will be described later, the pattern width of the resist 42 can be determined according to the width W1 of the core 43a.

The first sacrificial films 41a, 41b, and 41c may be formed of the same material, or may be formed of different materials from one another. In addition, the second sacrificial films 42a and 42b may be formed of the same material, or may be formed of different materials from one another. Note that, however, it is required to have a high etching selective ratio between the materials of the first sacrificial films 41a, 41b, and 41c and the materials of the second sacrificial films 42a and 42b. In addition, the materials of the first sacrificial films 41a, 41b, and 41c are required to have a high etching selective ratio to the material of the processed member 1. For example, if the processed member 1 is made of SiO₂, the material to be used for the first sacrificial films 41a, 41b, and 41c may be: an insulating material, such as SiN, C, or SiC; a metal, such as W, Ti, Al, or Ta; or a nitride or an oxide of any of these metals. The materials of the second sacrificial films 42a and 42b may be selected those having a high etching selective ratio to the materials of the first sacrificial films 41a, 41b, and 41c from among the same material candidates as those for the first sacrificial films 41a, 41b, and 41c. Moreover, since the materials of the second sacrificial films 42a and 42b do not necessarily have a high etching selective ratio to the material of the processed member 1, the same material as that of the processed member 1 may be used for the second sacrificial films 42a and 42b.

Next, as illustrated in FIG. 5B, etching is performed using the resist 42 as a mask, so that the pattern of the resist 42 is transferred to the first sacrificial film 41a. As a result, the first sacrificial film 41a is processed to the core 43a. The etching of the first sacrificial film 41a is performed by RIE or the like.

Next, as illustrated in FIG. 5C, the second sacrificial film 42a is processed into a tapered dimension-adjustment film 44a. Since the width (the width of the lower surface) of the dimension-adjustment film 44a becomes substantially equal to the width W2 of a core 43b which will be described later, the width of the dimension-adjustment film 44a can be determined according to the width W2 of the core 43b. The processing of the second sacrificial film 42a into the dimension-adjustment film 44a is performed, for example, under conditions where a large amount of reaction product is deposited in etching by RIE or the like.

Next, as illustrated in FIG. 5D, etching is performed using the resist 42 and the dimension-adjustment film 44a, so that the pattern of the dimension-adjustment film 44a is transferred to the first sacrificial film 41b. As a result the first sacrificial film 41b is processed into the core 43b. The etching of the first sacrificial film 41b is performed by RIE or the like.

Next, as illustrated in FIG. 5E, the second sacrificial film 42b is processed into a tapered dimension-adjustment film 44b. Since the width (the width of the lower surface) of the dimension-adjustment film 44b becomes substantially equal to the width W3 of a core 43c which will be described later, the width of the dimension-adjustment film 44a can be determined according to the width W3 of a core 43c. The processing of the second sacrificial film 42a into the dimension-adjustment film 44b is performed in the same way as that for the dimension-adjustment film 44a. Note that, it is permissible that exposed part of the dimension-adjustment film 44a is scraped in this process.

Next, as illustrated in FIG. 5F, etching is performed using the resist 42 as well as the dimension-adjustment films 44a and 44b as a mask, so that the pattern of the dimension-adjustment film 44b is transferred to the first sacrificial film 41c. As a result, the first sacrificial film 41c is processed into the core 43c. The etching of the first sacrificial film 41c is performed by RIE or the like.

Next, as illustrated in FIG. 5G, after the resist 42 is removed, a coating film 45 is formed by CVD or the like so as to conformally cover the side surfaces of cores 43a, 43b, and 43c as well as the sloping surfaces of the dimension-adjustment films 44a and 44b. Here, the thickness of the coating film 45 becomes substantially equal to the width Ws of a sidewall mask 46 which will be described later.

Next, as illustrated in FIG. 5H, the coating film 45 is partially removed by RIE or the like in such a manner that portions of the coating film 45, which are located respectively on the side surfaces of the cores 43a, 43b, and 43c, are left remaining. In this way, the coating film 45 is processed into the sidewall masks 46. Here, Ws denotes the width of each sidewall mask 46.

Next, as illustrated in FIG. 5I, etching is performed using the sidewall masks 46 as a mask, so that the core 43a are removed and that the cores 43b and 43c, the dimension-adjustment films 44a and 44b are partially removed at their portions which are not covered with the sidewall masks 46 from above. As a result, an etching mask 47 is obtained, which is formed of the sidewall masks 46 and portions, which remain just below the sidewall masks 46, of the cores 43b and 43c as well as the dimension-adjustment films 44a and 44b. The etching of the cores 43a, 43b, and 43c as well as the dimension-adjustment films 44a and 44b is performed by RIE or the like.

Next, as illustrated in FIG. 5J, etching is performed using the etching mask 47 as a mask, so that the processed member 1 is patterned. Here, the pattern pitch of the line-and-space pattern formed in the processed member 1 is denoted by P2. Note that, the width and interval of the line-and-space pattern formed in the processed member 1 are not necessarily constant. In the case where the width and interval of the line-and-space pattern are not constant, the pattern pitch P2 is also not constant. The etching of the processed member 1 is performed by RIE or the like.

Next, as illustrated in FIG. 5K, the etching mask 47 on the processed member 1 is removed. The removal of the etching mask 47 is performed by wet processing, RIE, or the like.

According to the fourth embodiment, it is possible, as in the above-described embodiments, to form a finer line-and-space pattern than that by the conventional pattern-forming method using a sidewall mask.

In addition, if a line-and-space pattern having constant width and constant interval is to be formed in the processed member 1 by the above-described method, the pattern pitch Pi of the resist 42 is constant, and the relation expressed by the following mathematical formulas may be satisfied:

$${W}_{1} = {W}_{s} = \frac{1}{12} {P}_{1} \\ {W}_{2} = \frac{5}{12} {P}_{1} \\ {W}_{3} = \frac{9}{12} {P}_{1} \qquad [ Mathematical Formulas 7 ]$$

where P1 denotes the pattern pitch, W1 denotes the width of the core 43a, W2 denotes the width of the core 43b, W3 denotes the width of the core 43c, and Ws denotes the width of each sidewall mask 46.

Here, W1 in Mathematical Formulas 7 is equal to a value obtained by substituting 3 and 1 respectively into m and n in the formula of Wn in Mathematical Formulas 1 described above. W2 in Mathematical Formulas 7 is equal to a value obtained by substituting 3 and 2 respectively into m and n in the formula of Wn in Mathematical Formulas 1 described above. W3 in Mathematical Formulas 7 is equal to a value obtained by substituting 3 and 3 respectively into m and n in the formula of Wn in Mathematical Formulas 1 described above. Ws in Mathematical Formulas 7 is equal to a value obtained by substituting 3 into m in the formula of Ws in Mathematical Formulas 1 described before.

In this case, the width and the interval of the pattern formed in the processed member 1 are equal to Ws, and thus, the pitch P2 of the pattern is constant and is expressed by the following mathematical formula:

$${P}_{2} = 2 {W}_{s} = \frac{1}{6} {P}_{1} \qquad [ Mathematical Formula 8 ]$$

Specifically, if the pattern pitch P1 of the resist 42 is a limit pitch for exposure of lithography, the fourth embodiment allows a pattern with a pitch that is one-sixth of the limit pitch for exposure to be formed on the processed member 1.

Here, P2 in Mathematical Formula 8 is equal to a value obtained by substituting 3 into m in the formula of Pn in Mathematical Formula 2 described before.

Note that, in the fourth embodiment, four or more stages of cores may be formed by using four or more first sacrificial films. In this case, if m denotes the number of stages of cores (m is a positive integer), the relation expressed by Mathematical Formulas 1 described above may be satisfied in order to form a line-and-space pattern with constant width and interval in the processed member 1, where P1 denotes the pattern pitch of the resist 42 (the pitch of each of the first to m-th cores from the top), Wn denotes the width of the n-th core from the top (n is an integer between 1 and m inclusive), and Ws denotes the width of each sidewall mask 46. As a result, the pattern with the pitch P2 expressed by Mathematical Formula 2 described above is formed in the processed member 1.

In this case, the pattern width of the resist 42 patterned by lithography, RIE, and the like in the process illustrated in FIG. 3A becomes substantially equal to the width W1 of the first core. In addition, the width of the n-th dimension-adjustment film from the top is equal to the width of the n+1-th core from the top formed just below the n-th dimension-adjustment film, and first to m−1-th dimension-adjustment films are formed from the top.

### Fifth Embodiment

The fifth embodiment corresponds to a combination of the first embodiment with the fourth embodiment, and is different from the first embodiment in that a plurality of second sacrificial films are formed and that three or more stages of cores are formed. Note that, the same points in the fifth embodiment as those in the first and second embodiments are not described or are described in brief.

Hereinafter, a case of forming three stages of cores (three stages of sidewall masks) will be described as an example. In practice, however, it is possible to form any number of two or more stages of cores as long as a desired processing accuracy is maintained.

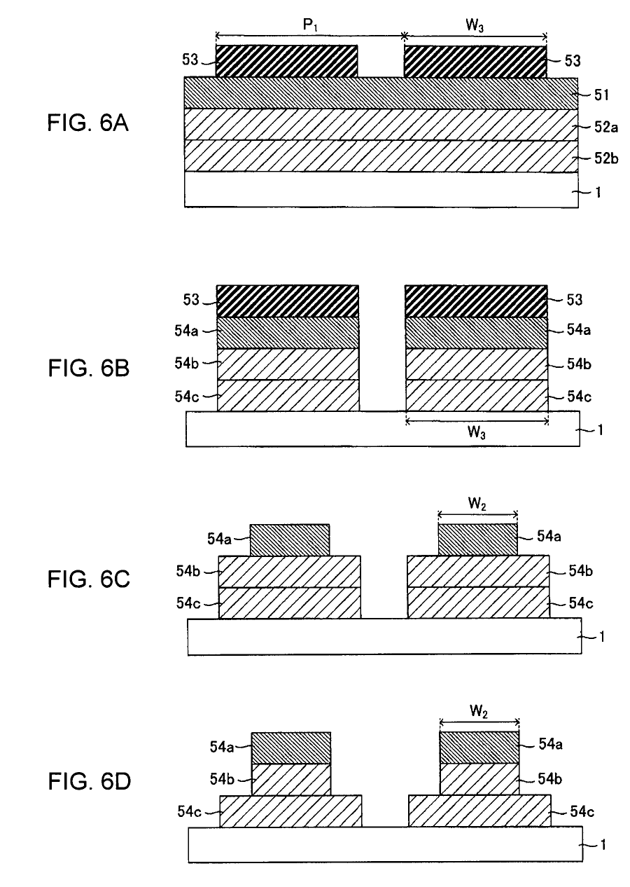

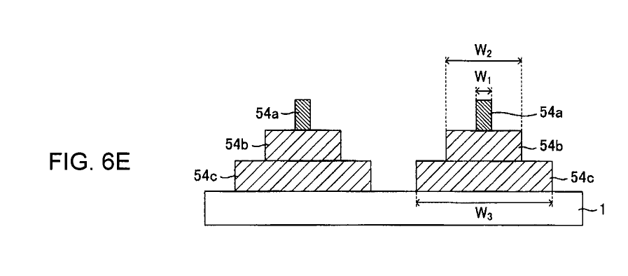

FIGS. 6A to 6E are cross-sectional views illustrating processes of manufacturing a semiconductor device according to the fifth embodiment.

First, as illustrated in FIG. 6A, second sacrificial films 52b and 52a, a first sacrificial film 51, as well as a resist 53 having a line-and-space pattern with a pitch P1 are sequentially stacked on a processed member 1 formed on an unillustrated semiconductor substrate, for example. Note that, the pitch P1 is not necessarily constant. In addition, an etching stopper film having a high etching selective ratio to the second sacrificial films 52a and 52b may be formed between the second sacrificial films 52a and 52b.

The resist 53 is patterned by lithography, RIE, and the like. Since the pattern width of the resist 53 becomes substantially equal to the width W3 of a core 54c which will be described later, the pattern width of the resist 53 can be determined according to the width W3 of the core 54c.

The materials of the first sacrificial film 51 as well as the second sacrificial films 52a and 52b to be combined are selected from those having high etching selective ratios. The first sacrificial film 51 as well as the second sacrificial films 52a and 52b may be formed of the same materials as those of the first sacrificial film 11 and the second sacrificial film 12 in the first embodiment.

In addition, the second sacrificial films 52a and 52b may be formed of the same material, or may be formed of different materials from each other. Alternatively, the second sacrificial films 52a and 52b may be integrally formed of a single material. Moreover, each of the materials of the first sacrificial film 51 as well as the second sacrificial films 52a and 52b is required to have a high etching selective ratio to the material of the processed member 1.

Next, as illustrated in FIG. 6B, etching is performed using the resist 53 as a mask, so that the pattern of the resist 53 is transferred to the first sacrificial film 51 as well as the second sacrificial films 52a and 52b. As a result, the first sacrificial film 51 as well as the second sacrificial films 52a and 52b are processed respectively into cores 54a, 54b, and 54c. The etching of the first sacrificial film 51 as well as the second sacrificial films 52a and 52b is performed by RIE or the like.

Next, as illustrated in FIG. 6C, the core 54a is subjected to a slimming process by wet processing or the like so as to have a reduced width. Here, since the width of the core 54a after the slimming process becomes substantially equal to the width W2 of the core 54b which will be described later, the width of the core 54a after the slimming process can be determined according to the width W2 of the core 54b. Note that, the resist 53 is removed before or after the slimming process.

Next, as illustrated in FIG. 6D, etching is performed using the core 54a as a mask, so that the pattern of the core 54a is transferred to the core 54b. The etching of the core 54b is performed by RIE or the like. At this time, if no etching stopper film is formed between the cores 54a and 54b, it is preferable to inhibit the etching from eroding the core 54c by controlling the etching time, or the like.

Next, as illustrated in FIG. 6E, the core 54a is subjected again to a slimming process by wet etching so as to have a further reduced width. Here, W1 denotes the width of the core 54a after the slimming process.

Thereafter, the processes after the process of forming the coating film 15 illustrated in FIG. 2D are performed in the same manner as that in the first embodiment.

According to the fifth embodiment, it is possible to form a finer line-and-space pattern than that of the first embodiment by increasing the number of stages of cores.

In addition, if a line-and-space pattern having constant width and constant interval is to be formed in the processed member by the above-described method, the pattern pitch P1 of the resist 53 is constant, and the relation expressed by the following mathematical formulas may be satisfied:

$${W}_{1} = {W}_{s} = \frac{1}{12} {P}_{1} \\ {W}_{2} = \frac{5}{12} {P}_{1} \\ {W}_{3} = \frac{9}{12} {P}_{1} \qquad [ Mathematical Formulas 9 ]$$

where P1 denotes the pattern pitch, W1 denotes the width of the core 54a, W2 denotes the width of the core 54b, W3 denotes the width of the core 54c, and Ws denotes the width of each sidewall mask 16.

Here, W1 in Mathematical Formulas 9 is equal to a value obtained by substituting 3 and 1 respectively into m and n in the formula of Wn in Mathematical Formulas 1 described above. W2 in Mathematical Formulas 9 is equal to a value obtained by substituting 3 and 2 respectively into m and n in the formula of Wn in Mathematical Formulas 1 described above. W3 in Mathematical Formulas 9 is equal to a value obtained by substituting 3 and 3 respectively into m and n in the formula of Wn in Mathematical Formulas 1 described above. Ws in Mathematical Formulas 9 is equal to a value obtained by substituting 3 into m in the formula of Ws in Mathematical Formulas 1 described before.

In this case, the width and the interval of the pattern formed in the processed member 1 are equal to Ws, and thus, the pitch P2 of the pattern is constant and is expressed by the following mathematical formula:

$${P}_{2} = 2 {W}_{s} = \frac{1}{6} {P}_{1} \qquad [ Mathematical Formula 10 ]$$

Specifically, if the pattern pitch P1 of the resist 53 is a limit pitch for exposure of lithography, the fifth embodiment allows a pattern with a pitch that is one-sixth of the limit pitch for exposure to be formed on the processed member 1.

Here, P2 in Mathematical Formula 10 is equal to a value obtained by substituting 3 into m in the formula of Pn in Mathematical Formula 2 described before.

Note that, in the fifth embodiment, four or more stages of cores may be formed by using four or more first sacrificial films. In this case, if m denotes the number of stages of cores (m is a positive integer), the relation expressed by Mathematical Formulas 1 described above may be satisfied in order to form a line-and-space pattern with constant width and interval in the processed member 1, where P1 denotes the pattern pitch of the resist 53 (the pitch of each of the first to m-th cores from the top), Wn denotes the width of the n-th core from the top (n is an integer between 1 and m inclusive), and Ws denotes the width of each sidewall mask 16. As a result, the pattern with the pitch P2 expressed by Mathematical Formula 2 described above is formed in the processed member 1.

In this case, the pattern width of the resist 53 patterned by lithography, RIE, and the like in the process illustrated in FIG. 6A becomes substantially equal to the width Wm of the m-th core from the top (the lowermost core). In addition, the pattern width of the core 54a having the reduced width by the slimming process in the process illustrated in FIG. 6C becomes substantially equal to the width Wm−1 of the m−1-th core (the second core from the bottom) from the top. Moreover, the pattern width of the core 54a having the further reduced width by the slimming process in the process illustrated in FIG. 6E becomes substantially equal to the width Wm−2 of the m−2-th core (the third core from the bottom) from the top. Subsequently, the slimming of the core 54a and the etching, using as a mask the core 54a subjected to the slimming process, of the cores therebelow are repeated in the same manner as described above until the pattern width of the core 54a becomes equal to the width W1 of the uppermost core. The slimming process on the core 54a is performed m−1 times in total.

Embodiments of the invention have been described with reference to the examples. However, the invention is not limited thereto.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A method of manufacturing a semiconductor device, comprising:
forming a second core on a member to be processed, and a first core on the second core, the second core located below the first core and having a width larger than that of the first core;
forming a coating film on a top surface and side surfaces of the first core, and a top surface and side surfaces of the second core;
processing the coating film into sidewall masks by partially removing the coating film in a manner that portions of the coating film, which are located on the side surfaces of the first and second cores, are left remaining;
etching the first and second cores by using the sidewall masks as a mask so as to remove the first core and portions of the second core which are not covered with the sidewall masks from above, so that an etching mask including the sidewall masks and portions of the second core which remain directly below the sidewall masks is formed; and
etching the member by using the etching mask as a mask, so that the member is patterned.

2. The method of claim 1, wherein
the forming the first and second cores includes:
forming a sacrificial layer and a resist on the member, the sacrificial layer made of a first layer and a second layer located below the first layer, the resist located above the sacrificial layer and having a predetermined pattern;
etching the first layer and the second layer by using the resist as a mask, so that the first and second layers are processed respectively into the first and second cores; and
reducing the width of the first core by performing one of a slimming process on the first core and an etching process on the first core by using as a mask the resist subjected to a slimming process.

3. The method of claim 1, wherein
the forming the first and second cores includes:
stacking a second sacrificial film, a third sacrificial film, a first sacrificial film, and a resist having a predetermined pattern sequentially on the member;
etching the first sacrificial film by using the resist as a mask, so that the first sacrificial film is processed into the first core;
processing the third sacrificial film into a tapered shape having slopes on both sides of the first core; and
etching the second sacrificial film by using as a mask the resist and the third sacrificial film having the tapered shape, so that the second sacrificial film is processed into the second core.

4. The method of claim 1, wherein
the forming the first and second cores includes directly embossing material films for the first and second cores by using a template having a three-dimensional concave and convex pattern corresponding to shapes of the first and second cores.

5. The method of claim 1, wherein
the forming the first and second cores includes embossing a resist film formed on the material films by using the template, and then, transferring a resultant shape of the resist film to the material films by etching.

6. A method for manufacturing a semiconductor device, comprising:
forming a plurality of m cores (m is a positive integer) at an arrangement pitch P sequentially on a member to be processed, the m cores having successively increasing widths from the uppermost core;
forming a coating film, so that side surfaces of the respective m cores are covered with the coating film;
processing the coating film into sidewall masks by partially removing the coating film in a manner that portions of the coating film, which are located respectively on the side surfaces of the m cores, are left remaining;
etching the m cores by using the sidewall masks as a mask so as to remove the first core at the top among the m cores and to remove portions, which are not covered with the sidewall masks from above, of the second to m-th cores from the top, thereby forming an etching mask including the sidewall masks and portions, which remain directly below the sidewall masks, of the second to the m-th cores; and
etching the member by using the etching mask as a mask, so that the member is patterned, wherein
the m cores are formed so that the width of the n-th core (n is an integer between 1 and m inclusive) from the top becomes approximately (4n−3)P/(4m), and
each of the sidewall masks is formed to have a width of approximately P/(4m).

7. The method of claim 6, wherein
the forming the plurality of m cores includes:
forming a sacrificial layer and a resist on the member, the sacrificial layer made of a first layer and a second layer located below the first layer, the resist located above the sacrificial layer and having a predetermined pattern;
etching the first layer and the second layer by using the resist as a mask, so that the first and second layers are processed respectively into the m cores; and
reducing the width of a first core which is provided in top of the m cores, by performing one of a slimming process on the first core and an etching process on the first core by using as a mask the resist subjected to a slimming process.

8. The method of claim 6, wherein
the forming the plurality of m cores includes:
stacking a second sacrificial film, a third sacrificial film, a first sacrificial film, and a resist having a predetermined pattern sequentially on the member;
etching the first sacrificial film by using the resist as a mask, so that the first sacrificial film is processed into a first core which is provided in top of the m cores;
processing the third sacrificial film into a tapered shape having slopes on both sides of the first core; and
etching the second sacrificial film by using as a mask the resist and the third sacrificial film having the tapered shape, so that the second sacrificial film is processed into a second core, which is provided under the first core in the m cores.

9. The method of claim 6, wherein
the forming the plurality of m cores includes directly embossing material films for the m cores by using a template having a three-dimensional concave and convex pattern corresponding to shapes of the m cores.

10. The method of claim 6, wherein
the forming the plurality of m cores includes embossing a resist film formed on the material films by using the template, and then, transferring a resultant shape of the resist film to the material films by etching.
